(19) United States
(12) Patent Application Publication
(10) Pub. No.: US 2020/0020624 A1
(43) Pub. Date: Jan. 16, 2020

(54) SUBSTRATE-EMBEDDED SUBSTRATE

(71) Applicant: QUALCOMM Incorporated, San Diego, CA (US)

(72) Inventors: Kuiwon KANG, San Diego, CA (US); Joan Rey Villarba BUOT, Escondido, CA (US); Soumyadipta BASU, San Diego, CA (US); Charles David PAYNTER, Encinitas, CA (US)

(21) Appl. No.: 16/030,936

(22) Filed: Jul. 10, 2018

(51) Int. Cl. H01L 23/498; H01L 21/48; H01L 23/31

(52) U.S. Cl. CPC H01L 23/49833; H01L 23/49838; H01L 23/49822; H01L 25/16; H01L 21/4853; H01L 23/3114; H01L 23/3121; H01L 21/4857

(57) ABSTRACT

A chip package substrate and methods for fabricating the chip package substrate. An exemplary chip package substrate generally includes a first substrate and a second substrate embedded in the first substrate and having a plurality of layered traces embedded therein.

### FIELD OF THE DISCLOSURE

Certain aspects of the present disclosure generally relate to electronic circuits and, more particularly, to a chip package having an embedded trace substrate arranged in another substrate.

### DESCRIPTION OF RELATED ART

Certain semiconductor packaging is formed through layer-by-layer buildup on a central glass reinforced core material, for example, to enable fine routing and act as an interposer between the silicon and motherboard. This approach, however, may not provide sufficient routing density, especially between die interfaces where very fine routing between dies is desired

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include an improved chip package substrate.

Certain aspects of the present disclosure provide a chip package substrate. The chip package substrate generally includes a first substrate, and a second substrate embedded in the first substrate and having a plurality of layered traces embedded therein.

Certain aspects of the present disclosure provide a method of fabricating a chip package substrate. The method generally includes forming a first substrate having a plurality of layered traces embedded therein, and arranging the first substrate in a second substrate.

Certain aspects of the present disclosure provide a chip scale package. The chip scale package generally includes a first substrate, a second substrate embedded in the first substrate and having a plurality of layered traces embedded therein, a semiconductor die arranged above the second substrate, an insulation buildup film arranged below the first substrate and the second substrate, and a layer of solder resist arranged below the insulation buildup film.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 illustrates a cross-sectional view of an example chip package, in accordance with certain aspects of the present disclosure.

FIG. 2 illustrates an exploded view of the example chip package, in accordance with certain aspects of the present disclosure.

FIG. 3 illustrates a cross-sectional view of an example chip package having additional surface mount components, in accordance with certain aspects of the present disclosure.

FIG. 4 illustrates a cross-sectional view of an example chip package having an integrated component, in accordance with certain aspects of the present disclosure.

FIG. 5 is a flow diagram of example operations for fabricating a chip package substrate, in accordance with certain aspects of the present disclosure.

### DETAILED DESCRIPTION

Aspects of the present disclosure provide chip packages having an embedded trace substrate and methods for fabricating the chip packages.

The following description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim. The word “exemplary” is used herein to mean “serving as an example, instance, or illustration.” Any aspect described herein as “exemplary” is not necessarily to be construed as preferred or advantageous over other aspects.

### Example Substrate-Embedded Substrate

Certain chip packages using a semi-additive process (SAP) to form the chip, such as a flip chip ball grid array (FCBGA), face difficulties in routing traces on the surface due to poor pattern adhesion. For example, certain chip packages formed using the SAP have a minimum trace width of 16 μm on an open solder resist area due to issues of trace peel off. This trace width places limits on the bump pitch and routing capabilities of the traces. Reducing the trace width, for example, by about half, enables a reduction of the pad size of the chip package, which may also improve the performance of the chip package and reduce fabrication costs.

As further described herein, an embedded trace substrate (ETS) may be used to reduce the trace width and space between two bumps. Miniaturizing the chip package enables the reduction of the chip's power consumption and fabricating costs. The ETS provides a finer bump pitch with a reduced size for coupling to an electronic component, such as a semiconductor die. This enables the chip package to provide finer line spacings and line widths, which enables finer trace routing.

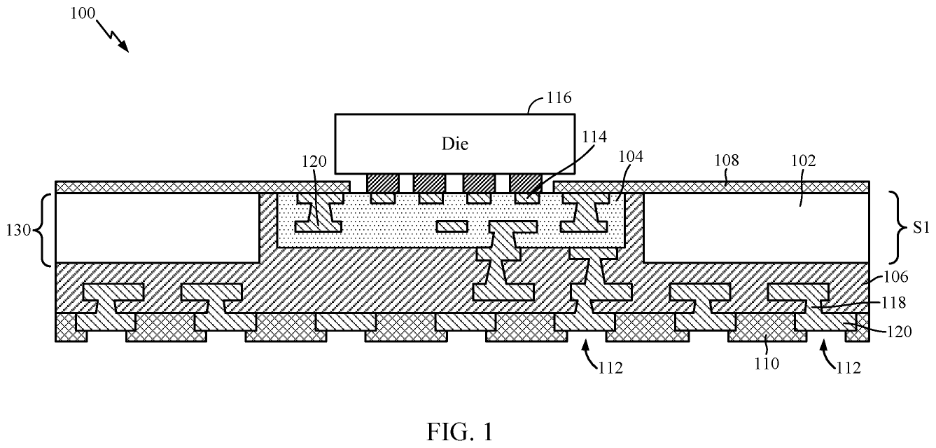

FIG. 1 illustrates a cross-sectional view of an example chip package 100, in accordance with certain aspects of the present disclosure. As shown, the chip package 100 includes a first substrate 102 and a second substrate 104 embedded in the first substrate 102. The second substrate 104 has a plurality of layered traces embedded therein.

The chip package 100 may be implemented as a chip scale package, such as a wafer level chip scale package having a package size that is near the die size. For certain aspects, a chip scale package may have package size that is <1.2 times the size of the die and surface mountable. The chip package 100 may be used to package various electronic circuits, such as a system on a chip (SoC), a modem, a radio frequency front-end (RFFE) circuit, memory, a general purpose processor, a digital signal processor (DSP), an image processor, a graphics processing unit (GPU), a central processing unit (CPU), an application specific integrated circuit (ASIC), a field programmable gate array (FPGA) or other programmable logic device (PLD), discrete gate or transistor logic, discrete hardware components, any suitable semiconductor device, or any combination thereof.

The first substrate 102 may include a core dielectric material or a substrate material having at least two layers. The core dielectric material may be a copper-clad laminate or clad with any other suitable conductive material. The first substrate 102 may have a thickness 51 in a range of 150 to 400 μm.

The second substrate 104 may be a coreless ETS and include a pre-impregnated (PPG) dielectric material. In certain aspects, the ETS may have a circuit pattern (e.g., traces and integrated passive components) embedded in the PPG. The second substrate 104 may have two, three, four, or more layers of embedded traces. As an example of three layers of embedded traces, the second substrate 104 may have a first layer of traces, a first PPG layer arranged below the first layer of traces, a second layer of traces arranged below the first PPG layer, a second PPG layer arranged below the second layer of traces, and a third layer of traces arranged below the second PPG layer. The layer of traces may include various passive or active components such as resistors, transistors, capacitors, inductors, etc. The second substrate 104 may have pads 114 on its upper surface for coupling to an electronic component 116, such as a surface mount chip or semiconductor die.

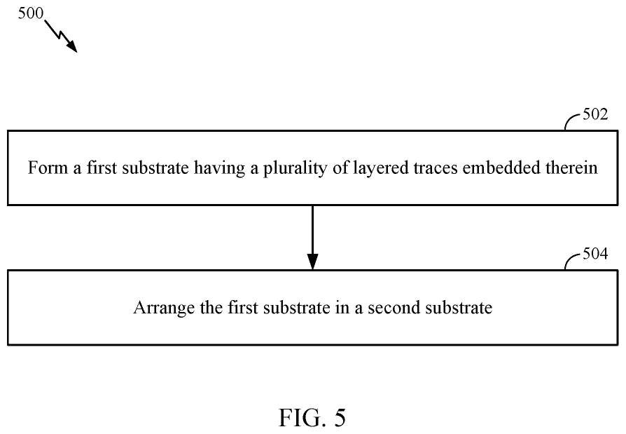

The first and second substrates 102, 104 may form a chip package substrate 130 as further described herein with respect to FIG. 5. With the integration of the ETS, the chip package substrate 130 enables finer routing of traces for coupling to the electronic component 116 by using a reduced trace width, line spacing, and/or line width via the pads 114 and traces 120 included in the second substrate 104.

The chip package 100 may also include an insulation layer 106 arranged below the first and second substrates 102, 104. For example, the insulation layer 106 may be implemented as a lamination of insulating buildup film. Through-package vias 118 may intersect the insulation layer 106 for coupling the first substrate 102, the second substrate 104, or both to an electronic component.

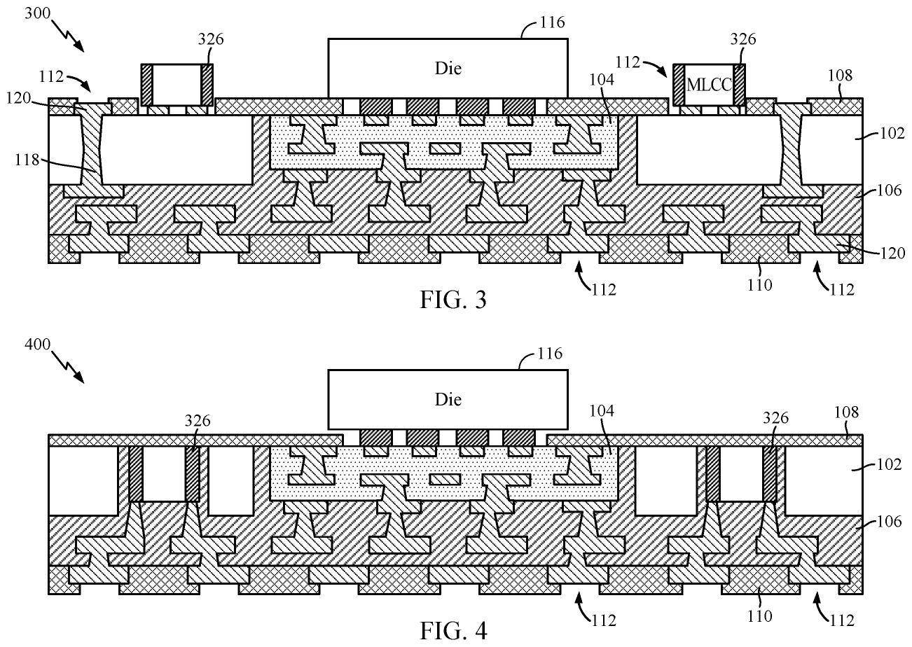

Layers of solder resist 108, 110 may be applied to surfaces of the chip package 100. For example, a top layer of solder resist 108 may be arranged above the first and second substrates 102, 104. The top layer of solder resist 108 may have one or more trenches 112 (shown in FIG. 3) for exposing traces 120 coupled to the first substrate 102 and/or the second substrate 104 for coupling to one or more electronic components (e.g., electronic component 116). For certain aspects, a bottom layer of solder resist 110 may be arranged below the insulation layer 106. The bottom layer of solder resist 110 may also have trenches 112 for exposing traces 120 coupled to the first substrate 102 and/or the second substrate 104 for coupling to an electronic component.

As illustrated in FIG. 1, the electronic component 116 is coupled to exposed pads 114 on the second substrate 104. The electronic component 116 may be implemented as any suitable surface mount device, such as a power management device or processing system.

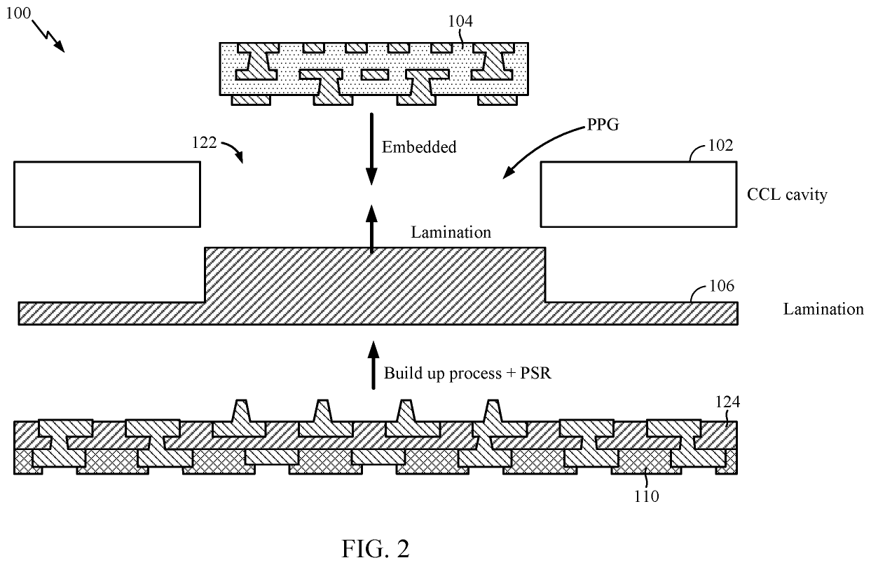

FIG. 2 illustrates an exploded view of the example chip package 100, in accordance with certain aspects of the present disclosure. As illustrated, the second substrate 104 may be formed using a coreless ETS fabrication process and arranged in a cavity 122 of the first substrate 102. The insulation layer 106 may be applied to the lower surfaces of the first and second substrates 102, 104, and for certain aspects, an interposer 124 may be arranged below the insulation layer 106 where the bottom layer of solder resist 110 is applied. For other aspects, the insulation layer 106 may serve as an interposer without the separate interposer 124 as depicted in FIG. 2.

FIG. 3 illustrates a cross-sectional view of an example chip package 300 having multiple surface mount components included therein, in accordance with certain aspects of the present disclosure. As shown, additional electronic components 326 may be arranged on an upper surface of the chip package 300. For example, the additional electronic components 326 may be implemented as multi-layered ceramic capacitors (MLCCs) arranged in the trenches 112 of the layers of solder resist 108, 110. The additional electronic components 326 may also include various electronic components such as memory modules, registers, logic arrays, switch networks, other types of passive components, etc. The chip package 300 also includes through-package vias 118 (e.g., micro-vias) that may couple the first substrate 102 and the second substrate 104 together.

FIG. 4 illustrates a cross-sectional view of an example chip package 400 having embedded components arranged therein, in accordance with certain aspects of the present disclosure. As shown, the additional electronic components 326 may be embedded in the chip package 400, below the upper surface and covered with the top layer of solder resist 108. For example, the additional electronic components 326 may be embedded in the first substrate 102 and/or the second substrate 104.

FIG. 5 is a flow diagram illustrating example operations 500 for fabricating a chip package substrate (e.g., chip package substrate 130), in accordance with certain aspects of the present disclosure. The operations 500 may begin, at block 502, with forming a first substrate (e.g., second substrate 104) having a plurality of layered traces embedded therein. For example, a coreless ETS may be formed having three or four layers of traces embedded between a PPG dielectric material.

At block 504, the first substrate (e.g., second substrate 104) is arranged in a second substrate (e.g., first substrate 102). For example, the coreless ETS (e.g., second substrate 104) may be arranged in a cavity of a core dielectric material (e.g., first substrate 102) as shown in FIG. 1.

In certain aspects, the operations 500 may further involve arranging an insulation layer (e.g., insulation layer 106) below the first and second substrates. For certain aspects, a layer of solder resist (e.g., solder resist 108, 110) may be arranged above the first and second substrates or below the insulation layer.

It should be appreciated that the chip packages described herein have a reduced trace width and pad size, which enables finer trace routing for coupling to semiconductor dies. This also enables the chip package to reduce its power consumption and cost to manufacture.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes and variations may be made in the arrangement, operation and details of the methods and apparatus described above without departing from the scope of the claims.

1. A chip package substrate comprising:
a first substrate; and
a second substrate embedded in the first substrate and having a plurality of layered traces embedded therein, wherein the second substrate is a coreless embedded trace substrate and wherein the plurality of layered traces are embedded in a pre-impregnated dielectric material of the second substrate.

2. The chip package substrate of claim 1, wherein the first substrate and the second substrate are coupled through one or more micro-vias.

3. The chip package substrate of claim 1, wherein the first substrate comprises at least one of a core dielectric material or a substrate material having at least two layers.

4. (canceled)

5. The chip package substrate of claim 1, wherein the first substrate has a thickness in a range of 150 to 400 μm.

6. The chip package substrate of claim 3, wherein the first substrate comprises a copper-clad laminate.

7. The chip package substrate of claim 1, wherein the second substrate comprises three or four layers of embedded traces.

8. The chip package substrate of claim 1, further comprising an insulation layer arranged below the first and second substrates, wherein the insulation layer comprises an insulating buildup film.

9. The chip package substrate of claim 8, further comprising a layer of solder resist arranged below the insulation layer and having trenches for exposing traces coupled to the second substrate for coupling to an electronic component.

10. The chip package substrate of claim 1, further comprising a layer of solder resist arranged above the first and second substrates and having one or more trenches for exposing traces coupled to the second substrate for coupling to an electronic component.

11. A method of fabricating a chip package substrate, comprising:
forming a first substrate having a plurality of layered traces embedded therein, wherein the first substrate is a coreless embedded trace substrate and wherein the plurality of layered traces are embedded in a pre-impregnated dielectric material of the first substrate; and
arranging the first substrate in a second substrate.

12. The method of claim 11, further comprising arranging an insulation layer below the first and second substrates.

13. The method of claim 12, wherein arranging the insulation layer comprises applying an insulating buildup film.

14. (canceled)

15. The method of claim 11, wherein the second substrate has a thickness in a range of 150 to 400 μm.

16. The method of claim 11, wherein the second substrate comprises at least one of a core dielectric material, a substrate material having at least two layers, or a copper-clad laminate.

17. The method of claim 11, wherein forming the first substrate comprises embedding three or four layers of traces in the first substrate.

18. The method of claim 12, further comprising arranging a layer of solder resist below the insulation layer.

19. The method of claim 18, wherein the layer of solder resist comprises trenches for exposing vias coupled to the first substrate for coupling to an electronic component.

20. A chip scale package comprising:
a first substrate;
a second substrate embedded in the first substrate and having a plurality of layered traces embedded therein, wherein the second substrate is a coreless embedded trace substrate and wherein the plurality of layered traces are embedded in a pre-impregnated dielectric material of the second substrate;
a semiconductor die arranged above the second substrate;
an insulation buildup film arranged below the first substrate and the second substrate; and
a layer of solder resist arranged below the insulation buildup film.

21. The chip package substrate of claim 1, wherein the first substrate includes an electronic component embedded in the first substrate.

22. The chip package substrate of claim 1, further comprising an electronic component disposed above the first substrate.
